(19) United States
(12) Patent Application Publication
(10) Pub. No.: US 2025/0326608 A1
(43) Pub. Date: Oct. 23, 2025

(54) METHOD AND APPARATUS TO OPTIMIZE AN ANTI-SWAY FUNCTION

(71) Applicant: Schneider Electric Industries SAS, Rueil Malmaison (FR)

(72) Inventors: Charles Blondel, Grenoble (FR); Nawfel Chegri, Grenoble (FR)

(73) Assignee: Schneider Electric Industries SAS, Rueil Malmaison (FR)

(21) Appl. No.: 19/096,876

(22) Filed: Apr. 1, 2025

(30) Foreign Application Priority Data
Apr. 23, 2024 (FR) 24315215.4

(51) Int. Cl. B66C 13/06; B66C 17/00; G06F 30/20

(52) U.S. Cl. CPC B66C 13/063; G06F 30/20; B66C 17/00

(57) ABSTRACT

For optimizing an anti-sway algorithm for the transport of a load by a hoisting appliance spanning a hoisting area and comprising a trolley, a reeving system and a tool handling the load, a control device is able to: record a time-domain signal representative of a measured angle of the load with respect to a vertical Z-axis during operation of the hoisting appliance; perform a frequency domain analysis on the recorded time-domain signal to estimate its frequency components; identify a primary sway frequency and a secondary sway frequency of the hoisting appliance among the estimated frequency components; filter the time-domain signal representative of a measured angle of the load with respect to a vertical Z-axis by a lowpass filter designed to reject the identified secondary sway frequency; and transport the load in the hoisting area by applying the anti-sway algorithm to the filtered signal.

### TECHNICAL FIELD

This disclosure pertains to the field of hoisting appliances such as cranes, gantry cranes or overhead travelling cranes. This disclosure notably relates to a method for an anti-sway function applied to a hoisting appliance that is spanning a warehouse, the hoisting appliance arranged for carrying a load suspended by cables from a trolley that can move with the hoisting appliance.

### BACKGROUND ART

Hoisting appliances 1 such as bridge cranes, gantry cranes or overhead travelling cranes usually comprise a trolley 2 which can move over a single girder or a set of rails 3 along a horizontal axis Y, as shown in FIG. 1. This first movement along the Y-axis is generally referred to as short travel movement and/or trolley movement. Depending on the type of appliance, the girder or the set of rails 3, also referred to as bridge, may also be movable along a horizontal axis X perpendicular to the Y-axis, thus enabling the trolley to be moved along both the X- and Y-axes. This second movement along the X-axis is generally referred to as long-travel movement and/or bridge, crane or gantry movement. The amount of available short travel along the Y-axis and long travel along the X-axis determines a hoisting area that is spanned by the hoist 1.

A tool 4, also called load suspension device, is associated with a reeving system having cables which pass through the trolley 2, the length of the cables 5 being controlled by the trolley 2 to vary, thereby enabling displacement of a load 6 along a vertical axis Z, referred to as hoisting movement.

Transferring a suspended load across a warehouse, a hall, shipyard, metallurgic or nuclear plant, requires an operator to be very careful to prevent people, obstacles or objects that are present within the hoisting area from being hit or damaged in any way. Hence, in addition to size, swinging of the suspended load, commonly referred to as sway, is something that the operator needs to take into account when manoeuvring the load across the working place along a trajectory within the boundaries of the hoisting area. Moreover, secondary sway phenomena may occur and disturb the normal operation of the hoisting appliance.

Anti-sway algorithms have been developed to reduce significantly sway of the load, and thus improve the mechanical stress of the crane, as well as increase the productivity and performance of operation of the hoisting appliance. In order to implement an antisway system providing high accuracy, high performance and able to work in a severe environment, a first solution is to use a close loop antisway offering better accuracy and performance, and a second solution is to use an open loop allowing harsh environment.

In either case, these antisway algorithms aim at mastering the main sway phenomenon, which is called the primary sway and which directly depends on the length of the pendulum. This primary sway generally has a long period, and cranes controls and dynamics can influence and master this kind of sway.

However, another sway phenomenon is called the secondary sway. It generally has a higher frequency than the primary sway, and is difficult, if not impossible, to control. The crane dynamics are too low and the only way to suppress this phenomenon is to wait for it to stop on its own.

Occurrence of a secondary sway reduces the effectiveness of the antisway systems, which are designed to correct the effect of the primary sway.

### SUMMARY

This disclosure improves the situation.

It is proposed a method for optimizing an anti-sway algorithm for the transport of a load by a hoisting appliance spanning a hoisting area and comprising a trolley, a reeving system and a tool handling the load, the method comprising in a control device:
recording a time-domain signal representative of a measured angle of the load with respect to a vertical Z-axis during operation of the hoisting appliance,
performing a frequency domain analysis on said recorded time-domain signal to estimate frequency components of said time-domain signal,
identifying a primary sway frequency and a secondary sway frequency of the hoisting appliance among said estimated frequency components,
filtering said time-domain signal representative of a measured angle of the load with respect to a vertical Z-axis by a lowpass filter designed to reject said identified secondary sway frequency,
transporting the load in the hoisting area by applying said anti-sway algorithm to said filtered signal.

In another aspect, it is proposed an apparatus for optimizing an anti-sway algorithm for the transport of a load by a hoisting appliance spanning a hoisting area and comprising a trolley, a reeving system and a tool handling the load, the apparatus comprising:
one or more network interfaces to communicate with a telecommunication network;
a processor coupled to the network interfaces and configured to execute one or more processes; and
a memory configured to store a process executable by the processor, the process when executed operable to:
   record a time-domain signal representative of a measured angle of the load with respect to a vertical Z-axis during operation of the hoisting appliance,
   perform a frequency domain analysis on said recorded time-domain signal to estimate frequency components of said time-domain signal, identify a primary sway frequency and a secondary sway frequency of the hoisting appliance among said estimated frequency components,
   filter said time-domain signal representative of a measured angle of the load with respect to a vertical Z-axis by a lowpass filter designed to reject said identified secondary sway frequency,
   transport the load in the hoisting area by applying said anti-sway algorithm to said filtered signal.

In another aspect, it is proposed a computer software comprising instructions to implement at least a part of a method as defined here when the software is executed by a processor. In another aspect, it is proposed a computer-readable non-transient recording medium on which a software is registered to implement the method as defined here when the software is executed by a processor.

The following features, can be optionally implemented, separately or in combination one with the others:
Recording is performed for a set of different lengths between the trolley and the tool and for a set of different masses of the load.

The set of different lengths between the trolley and the tool comprises five different lengths spanned between a minimum operating length and a maximum operating length between the trolley and the tool.

The set of different masses of the load comprises five different masses spanned between zero and a maximum mass of the load that can be transported by said hoisting appliance.

The frequency domain analysis is performed using a transform belonging to the group comprising:
a Discrete Fourier Transform;
a Fast Fourier Transform.

The measured angle of the load is recorded using an optical sensor set on the trolley cooperating with a beacon set on the tool.

The primary and secondary sway frequencies are identified for each operating point of the hoisting appliance, an operating point being associated with a couple comprising a value of the mass of the load and a value of the length between the load and the trolley.

The method further comprises filtering the signal representative of the measured angle of the load by a high-pass filter designed to detect the secondary sway frequency, and, when a secondary sway is detected, stopping the hoisting appliance until the detected secondary sway is below a determined amplitude threshold.

### BRIEF DESCRIPTION OF DRAWINGS

Other features, details and advantages will be shown in the following detailed description and on the figures, on which:

FIG. 1 shows schematically an example of a hoisting appliance.

FIG. 2 shows schematically an example of a communication system for optimizing an anti-sway algorithm for the transport of a load by the hoisting appliance of FIG. 1 according to an embodiment.

FIG. 3 illustrates elements of the hoisting appliance involved in a secondary sway.

FIG. 4 illustrates a difference between the primary sway and the secondary sway.

FIG. 5 illustrates a double pendulum model associated with the hoisting appliance of FIG. 1.

FIG. 6 illustrates the primary sway phenomenon on the double pendulum model of FIG. 5.

FIG. 7 illustrates the secondary sway phenomenon on the double pendulum model of FIG. 5.

FIG. 8 shows the signal representative of the angle of the load measured by an angle sensor during operation of the hoisting appliance.

FIG. 9 is a flow chart illustrating a method for optimizing an anti-sway algorithm for the transport of a load by the hoisting appliance of FIG. 1 according to an embodiment.

FIG. 10 illustrates the frequency spectrum of the time-domain signal shown on FIG. 8.

FIG. 11 schematically illustrates filtering of the measured angle to reject secondary sway frequencies according to an embodiment.

FIG. 12 is a flow chart illustrating further optional steps of the method for optimizing an anti-sway algorithm of FIG. 9 according to an embodiment.

FIG. 13 schematically illustrates filtering of the measured angle to keep only secondary sway frequencies according to an embodiment.

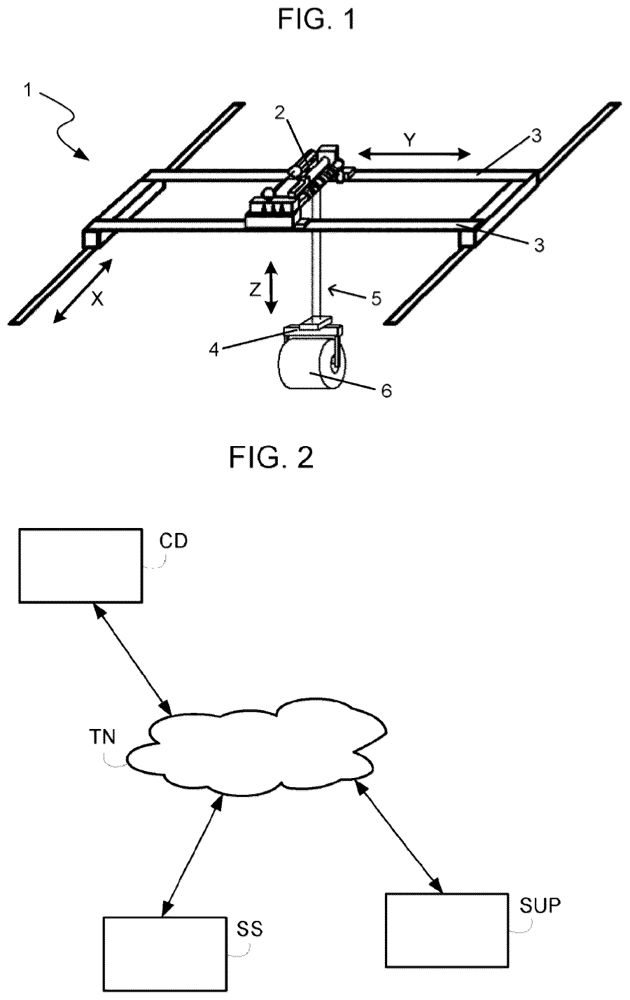

The same reference number represents the same element or the same type of element on all drawings.

It should be appreciated by those skilled in the art that any block diagrams herein represent conceptual views of illustrative systems embodying the principles of the present subject matter. Similarly, it will be appreciated that any flow charts, flow diagrams, state transition diagrams, pseudo code and the like represent various processes which may be substantially represented in computer readable medium and so executed by a computer or processor, whether or not such computer or processor is explicitly shown.

### DESCRIPTION OF EMBODIMENTS

The figures and the following description illustrate specific exemplary embodiments of the disclosure. It will thus be appreciated that those skilled in the art will be able to devise various arrangements that, although not explicitly described or shown herein, embody the principles of the disclosure and are included within its scope. Furthermore, any examples described herein are intended to aid in understanding the principles of the disclosure and are to be construed as being without limitation to such specifically recited examples and conditions. As a result, the disclosure is not limited to the specific embodiments or examples described below, but by the claims and their equivalents.

It is now referred to FIG. 2, which illustrates a communication system for optimizing an anti-sway function for the transport of a load by a hoisting appliance. This communication system comprises a control device CD, a set of sensors SS and a supervisory system SUP.

A hoisting area, such as a warehouse, a yard, a hall or other working area, is provided with a supervisory system SUP that is an IT control system for supervision of the hoisting area. The supervisory system provides information to the control device CD for trajectory execution, authorization i.e. access management, and security in general.

The control device CD is able to communicate with the supervisory system SUP and with the set of sensors SS through a telecommunication network TN. The telecommunication network may be a wired or wireless network, or a combination of wired and wireless networks. The telecommunication network can be associated with a packet network, for example, an IP (“Internet Protocol”) high-speed network such as the Internet or an intranet or even a company-specific private network. The control device CD may be Programmable Logic Controllers (PLC) and other automation device able to implement industrial processes and able to communicate with the supervisory system for exchanging data such as requests, inputs, control data, etc.

In one embodiment, the set of sensors SS includes a positioning system PS and an angle sensor AS. The angle sensor AS may take the form of an optical sensor, e.g. a camera, embarked on the trolley and looking for a beacon (or target) installed on the tool. For example, the beacon is set on the upper pulleys of the tool. The angle sensor AS may use infrared or optical technologies. It will be appreciated by the skilled persons that other types of angle sensors AS may also be used.

The positioning system PS may be linked to the trolley and is configured to measure the position of the trolley, and e.g., its speed parameter. The positioning system may comprise a radar system, including a radio emitter and a radio detector.

During a teaching phase for a specific load, the load is transported along different paths in the hoisting area. The teaching phase may be enriched during different operating sessions of the hoisting appliance. At consecutive time intervals or specific positions, the control device CD can receive measures of angle of the load with respect to the Z axis from the angle sensor AS. Such measurements may be successively performed for different lengths of the pendulum, i.e. different distances between the load and the trolley.

In an embodiment, such measurements are performed for five different lengths of the pendulum, browsing the range from the minimum length up to the maximum length of the hoisting motion of the crane.

Moreover, this teaching phase may be performed for different loads. For example, the measurements of angle are received by the control device CD for five different masses of the load, browsing a range from no load to a maximum mass of the load that can be transported by the hoisting appliance. In an embodiment, the angle measurements are received by the control device CD for five different masses of the load, comprised between zero and forty tons, in steps of ten tons.

Indeed, evolution of the system as a function of the length of the pendulum and of the mass of the load is somehow linear. Therefore, performing the teaching phase for five different lengths of the pendulum and five different masses of the load appears to be sufficient to efficiently extrapolate the measures over the whole operating range of the hoisting appliance. Enriching the teaching phase with additional masses of the load or additional lengths of the pendulum would lengthen the teaching phase without significantly improving the accuracy of the results thus obtained.

The control device CD may record the angle measurements in a look up table, LUT, associated to a couple [length of the pendulum, mass of the load].

The control device CD is configured to create a path to be followed by the crane for transporting a load from one place within the hoisting area to another. Usually, an anti-sway algorithm is used for the damping of sways of a load during the operation of the bridge crane, which provides the increase of a mechanism performance, reduces the risk of accidents and traumatic situations. Methods that are used to achieve this goal may include mathematical modeling and computer simulation. An anti-sway system is based on the use of a load angle sensor with internal variables of the electric drive system. For example, an anti-sway algorithm takes as inputs dynamic parameters of hoisting appliance comprising the current position of the trolley and the current angle of the load with respect to the trolley.

However, the anti-sway algorithm is designed to damp the primary sway of the load, which generally has a long period and directly depends on the length L of the pendulum, i.e. the distance between the load and the trolley. Cranes controls and dynamics can influence and master this primary sway, which frequency f is well-known and easy to calculate using the following formula, with g the free-fall acceleration

$$f = \frac{1}{2 π} \sqrt{\frac{g}{L}} \qquad [ Math . 1 ]$$

Another sway phenomenon, called the secondary sway, generally has a higher frequency and is difficult, if not impossible, to control. Indeed, dynamic of the crane is too low, as compared to the frequency of the secondary sway, and the only way to suppress this phenomenon is usually to wait until it ends by itself. The load cannot be safely deposited as long as this secondary sway persists. Hence, when secondary sway occurs, the hoisting appliance must be stopped, which reduces its productivity. Moreover, this secondary sway disturbs the anti-sway algorithm, and reduces its efficiency in damping the primary sway.

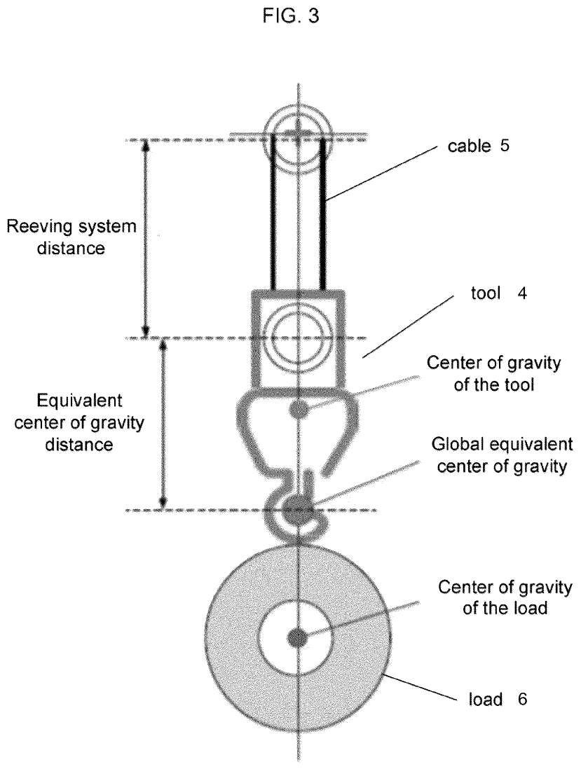

The frequency of this secondary sway depends on masses balance and distance between the different inertias, as will be more clearly understood in relation to FIG. 3, which illustrates some elements of the hoisting appliance involved in a secondary sway.

The hoisting appliance comprises a trolley 2 controlling the length of a cable 5 of a reeving system that is linked at the bottom to a tool 4 handling a load or product 6. The cable 5 is linked to the trolley via an upper block and is linked to the tool via a lower block. The position of the center of gravity of the tool 4 depends on the type of tool and the center of gravity of the load 6 is more or less at the middle of the load. The global equivalent center of gravity of the combination of the tool and the load is situated somewhere between the center of gravity of the tool and the center of gravity of the load. However, due to the complexity of the mechanical design of the hoisting appliance, it is difficult to determine with accuracy the exact position of these different centers of gravity.

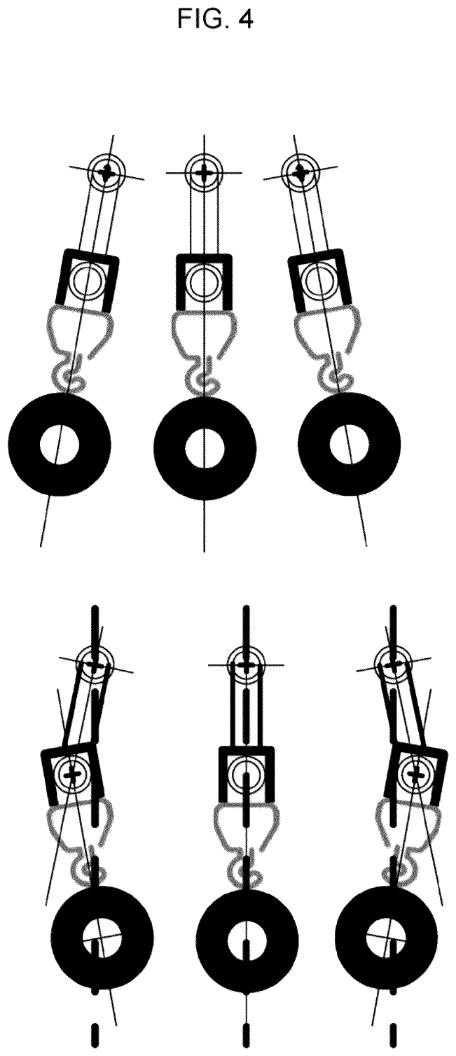

Referring to FIG. 4, the difference between the primary sway and the secondary sway is illustrated. In case of primary sway (FIG. 4 (a)), the load may balance in an arc below the trolley from the vertical Z axis, in a direction parallel to the trolley travel direction. The rotation axis is situated around the upper part of the reeving system linked to the trolley. In case of secondary sway (FIG. 4 (b)), the tool may further balance in an arc below the trolley from the axis of the global equivalent center of gravity, in a direction parallel to the trolley travel direction. The rotation axis is situated between the lower part of the reeving system linked to the tool and the center of gravity of the load.

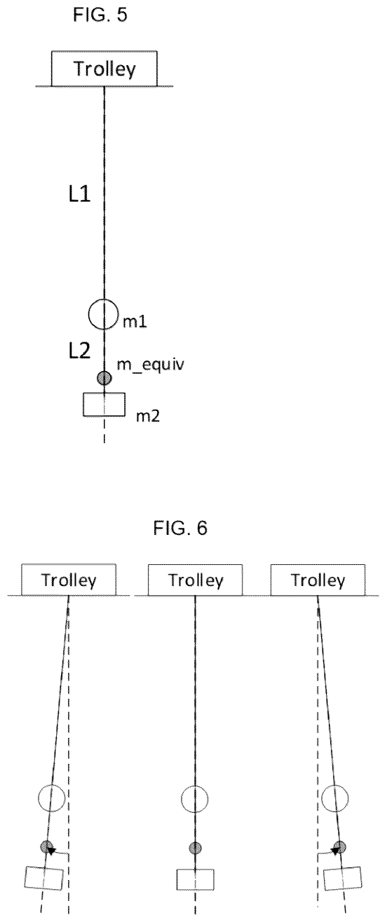

This combination of primary and secondary sway may be better understood through use of a double pendulum model, associated with the hoisting appliance of FIG. 3, as illustrated in FIG. 5. This double pendulum model is defined as a first pendulum (L1, m1) linked to a second pendulum (L2, m2). An equivalent mass m_equiv of m1 and m2 can be determined. Mass m1 corresponds to the mass of the tool pulleys; mass m2 corresponds to the mass of the tool and of the load; length L1 corresponds to the distance between the trolley and mass m1; length L2 corresponds to the distance between mass m1 and mass m2.

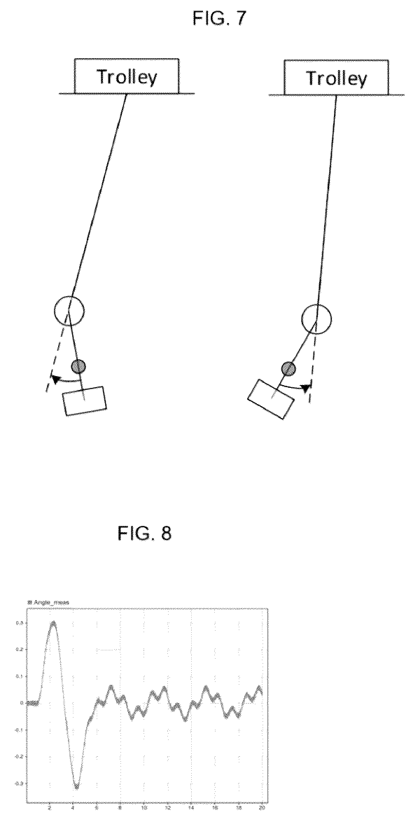

The measurement of a primary sway is observed between the vertical Z axis and the angle of the load at the position of the equivalent mass m_equiv, as illustrated in FIG. 6. The measurement of the secondary sway is observed between the axis of the first pendulum L1 and the axis of the second pendulum L2, as illustrated in FIG. 7.

However, for a given hoisting appliance, determining the values and positions of masses m1 and m2 of the associated double pendulum model is tricky. Due to the complexity of the mechanical design of the crane, the centers of gravity of its different components are difficult to position with accuracy. Length L1 depends on the distance between the upper pulley and the pulley located on the tool, but also depends on the reeving arrangement, which could be complex and influential. Length L2, masses m1 and m2 depend on the mechanical design of the tool and on the load. Load balance influences these different parameters, which moreover often differ from one crane to another.

However, if these different parameters of the double pendulum system could be determined, they could be used to calculate the frequencies of the secondary sway, which are given by the following formulae:

$$R = \frac{{m}_{1} + {m}_{2}}{{m}_{1}} - 1 \qquad [ Math . 2 ]$$

$$β = \sqrt{{( 1 + R )}^{2} {( \frac{1}{{L}_{1}} + \frac{1}{{L}_{2}} )}^{2} - 4 ( \frac{1 + R}{{L}_{1} {L}_{2}} )} \qquad [ Math . 3 ]$$

$${ω}_{+} = \frac{1}{2 π} \sqrt{\frac{g}{2} \sqrt{( 1 + R ) ( \frac{1}{{L}_{1}} + \frac{1}{{L}_{2}} ) + β}} \qquad [ Math . 4 ]$$

$${ω}_{-} = \frac{1}{2 π} \sqrt{\frac{g}{2} \sqrt{( 1 + R ) ( \frac{1}{{L}_{1}} + \frac{1}{{L}_{2}} ) - β}} \qquad [ Math . 5 ]$$

ω+ and ω₋ are the frequencies of the normal modes, corresponding to a slow in-phase mode and a fast out-of-phase mode.

The antisway algorithm usually receives as input the measurements from the angle sensor AS, to get real feedback on the hoisting system. As described above, the angle sensor AS may consist in a camera installed on the trolley which detects a target directly attached to the tool. However, when secondary sway occurs, the camera provides information to the control device CD, which are a combination of the primary and secondary sway, as illustrated in FIG. 8. FIG. 8 illustrates evolution over time of the angle of the load, as measured by the angle sensor AS. As may be observed on FIG. 8, the curve comprises high frequency components, corresponding to the secondary sway, superimposed on low frequency components, corresponding to the primary sway. According to prior art techniques, it is very difficult to isolate one or either sway from the other and to estimate the level of the secondary sway.

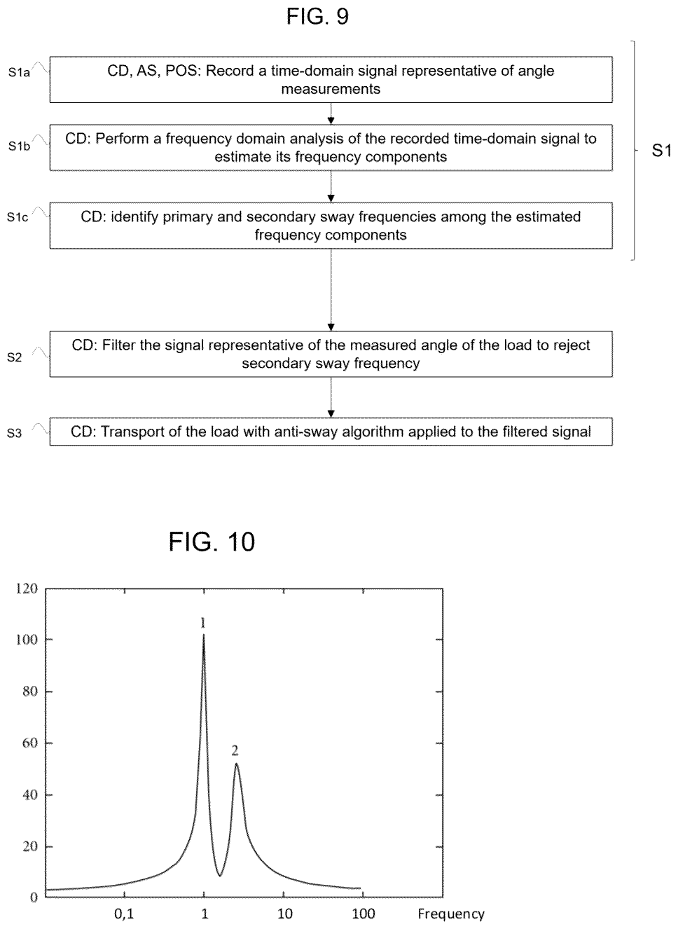

With reference to FIG. 9, a method for optimizing an anti-sway algorithm for the transport of a load by a hoisting appliance according to one embodiment of the invention comprises steps S1 to S3.

In step S1, the control device CD initiates a teaching phase for different loads and for different lengths of the pendulum, during which it receives and records measures from the set of sensors SS. During the teaching phase, the mass of the load may be varied by steps of ten tons, and the control device CD may receive measures of the angle of the load from the angle sensor AS for five different values of the mass of the load. Similarly, the length of the pendulum may be varied from a minimum to a maximum length of the pendulum to span the whole hoisting height, and the control device CD may receive measures of the angle of the load for five different length values. In an embodiment, these five length values are distributed at regular intervals throughout the range of possible crane operating lengths.

Hence, in a sub-step S1a, the control device CD records time-domain signals representative of an angle measurement of the load with respect to the Z-axis. To this purpose, it receives measurements of angle parameters of the load from the angle sensor AS at discrete or continuous time intervals and records corresponding time-domain signals, which are each associated with a given mass of the load and a given length of the pendulum. Each time-domain signal is associated with an operating point of the hoisting appliance, an operating point being associated with a couple comprising a value of the mass of the load and a value of the length between the load and the trolley.

In a sub-step S1b, the control device CD performs a frequency domain analysis of the recorded time-domain signal, using for example a Discrete Fourier Transform or a Fast Fourier Transform.

In an example, the input time-domain signal is denoted as x(t), and represents the measured angle of the load with respect to the Z axis. This time signal is sampled in the form of N samples noted {xₙ}=x₀, x₁, . . . , x_{N-1}. In an example, a Discrete Fourier transform of this time signal transforms this sequence of N samples into another sequence {Xₖ}=X₀, X₁, . . . , X_{N-1}, which can be expressed as:

$${X}_{k} = {\sum }_{n = 0}^{N - 1} {x}_{n} \cdot {e}^{- i 2 π \frac{k}{N} n} \qquad [ Math . 6 ]$$

Xₖ is the frequency domain representation of the signal at the frequency of index k, where k ranges from 0 to N−1 and represents the frequency bins. The above equation calculates the amplitudes and phases of the sinusoids that make up the input signal in the frequency domain. Indeed, the DFT formula is the cross correlation of the input sequence, xₙ, and a complex sinusoid at frequency N, and thus acts like a matched filter for that frequency. The DFT efficiently computes this transformation, allowing for a rapid analysis of the time-domain signals of the angle measurements in the method of FIG. 9, according to an embodiment.

FIG. 10 shows the frequency spectrum of the input time signal, as determined by such a frequency-domain analysis method. The magnitude of the signal is represented as a function of frequency on a logarithmic scale. As may be observed, such a frequency spectrum shows two main peaks, numbered 1 and 2, which correspond to the two main frequencies of the input signal. Indeed, it may be considered that; in the field of hoisting appliances, the spectrum of the input time signal representative of the angle measurements of the load, will only comprise two frequency peaks, respectively corresponding to the primary sway frequency and to the secondary sway frequency.

In a sub-step S1c, the control device CD then identifies, among the frequency components estimated in sub-step S1b, the primary sway frequency and the secondary sway frequency. Indeed, among the two frequency peaks of the frequency spectrum, the primary sway frequency may be identified as the lower frequency while the secondary sway frequency corresponds to the frequency of higher value. For example, the control device CD determines that the frequency of the primary sway is 1.637 Hz and that the frequency of the secondary sway is 6.927 Hz.

Primary and secondary sway frequencies may hence be assessed for each recorded input time signal, and hence for each operating point of the hoisting appliance (i.e. couple [mass of the load, length of the pendulum]). Interpolation between two operating points for which an input time signal has been recorded in sub-step S1a allows deriving the values of the primary and secondary sway frequencies for any other operating point of the hoisting appliance. Any type of interpolation may be used, such as linear interpolation, polynomial interpolation, spline interpolation, etc. However, the simplest linear interpolation may be sufficient to provide accurate results.

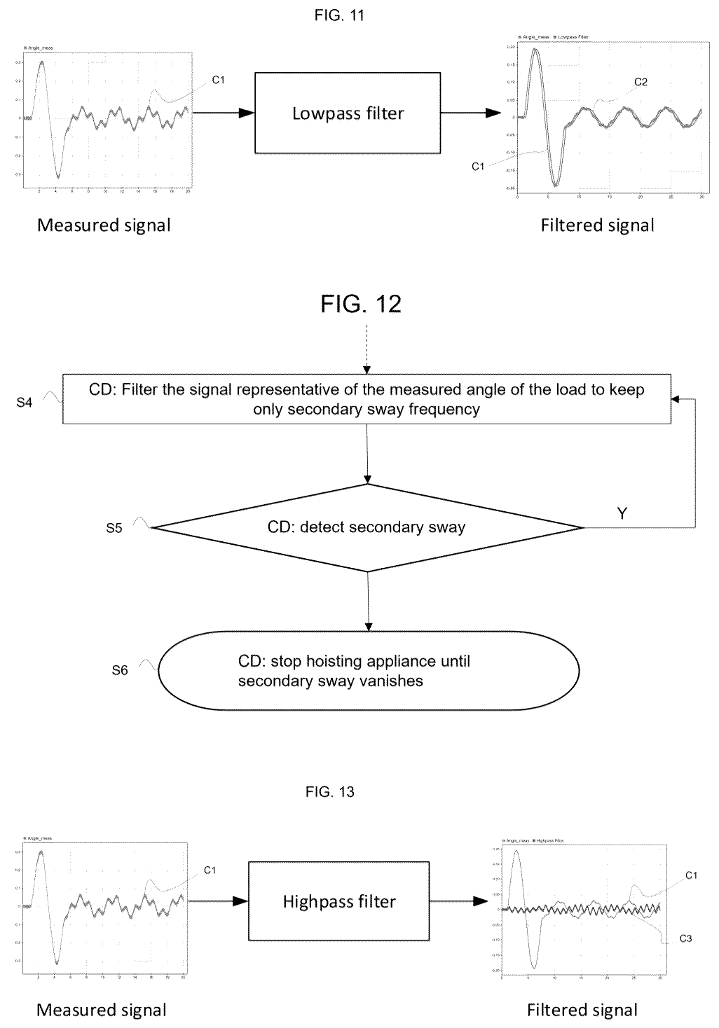

In step S2, during operation of the hoisting appliance, the control device CD receives, from the angle sensor AS, a signal representative of the measurement of the angle of the load as a function of time. The control device CD adjusts a dynamic lowpass filter, using the frequencies of the primary and secondary sway calculated in sub-step S1c, to reject the frequency components associated with the secondary sway and keep only the frequency components associated with the primary sway. The measured signal C1 received from the angle sensor AS is filtered using this adjusted dynamic lowpass filter, as illustrated in FIG. 11. The filtered signal is illustrated by curve C2 and can be used efficiently for controlling the crane.

In step S3, the control device CD generates a trajectory of the hoisting appliance for transporting a given load through the hoisting area from a starting point to a target point. The control device CD commands the trolley to start the transport of the load and uses the antisway algorithm to adapt the behavior of the trolley during the transport.

The antisway algorithm takes as input the filtered signal C2 representative of the measured angle of the load deprived from the secondary sway frequency components. This antisway algorithm may be any well-known antisway algorithm allowing to efficiently master the primary sway affecting the hoisting appliance.

In an embodiment, the steps of the method described in relation to FIG. 9 may be directly followed by the additional steps shown in FIG. 12 and further schematically illustrated in FIG. 13. In step S4, the control device CD may adjust a dynamic high-pass filter, using the frequencies of the primary and secondary sway identified in sub-step S1c, to reject the frequency components associated with the primary sway and keep only the frequency components associated with the secondary sway. The measured signal C1 received from the angle sensor AS may be filtered using this adjusted dynamic high-pass filter, as illustrated in FIG. 13, to detect presence of a secondary sway in step S5, when the hoisting appliance reaches its target destination. The filtered signal is illustrated by curve C3.

Indeed, it may be dangerous to deposit the load as long as the secondary sway is above a determined amplitude threshold. The control device CD may compare the amplitude of the filtered signal C3 to a determined amplitude threshold. If the amplitude of the filtered signal C3 is above the threshold, a secondary sway is detected. The control device sends commands for stopping the hoisting appliance until the amplitude of the filtered signal C3 is below the determined amplitude threshold, meaning the secondary sway has naturally vanished. The load can then be safely deposited, and operation of the hoisting appliance may start again.

An embodiment comprises a control device CD under the form of an apparatus comprising one or more processor(s) I/O interface(s), and a memory coupled to the processor(s). The processor(s) may be implemented as one or more microprocessors, microcomputers, microcontrollers, digital signal processors, central processing units, state machines, logic circuitries, and/or any devices that manipulate signals based on operational instructions. The processor(s) can be a single processing unit or a number of units, all of which could also include multiple computing units. Among other capabilities, the processor(s) are configured to fetch and execute computer-readable instructions stored in the memory.

The functions realized by the processor may be provided through the use of dedicated hardware as well as hardware capable of executing software in association with appropriate software. When provided by a processor, the functions may be provided by a single dedicated processor, by a single shared processor, or by a plurality of individual processors, some of which may be shared. Moreover, explicit use of the term “processor” should not be construed to refer exclusively to hardware capable of executing software, and may implicitly include, without limitation, digital signal processor (DSP) hardware, network processor, application specific integrated circuit (ASIC), field programmable gate array (FPGA), read only memory (ROM) for storing software, random access memory (RAM), and non volatile storage. Other hardware, conventional and/or custom, may also be included.

The memory may include any computer-readable medium known in the art including, for example, volatile memory, such as static random access memory (SRAM) and dynamic random access memory (DRAM), and/or non-volatile memory, such as read-only memory (ROM, erasable programmable ROM, flash memories, hard disks, optical disks, and magnetic tapes). The memory includes modules and data. The modules include routines, programs, objects, components, data structures, etc., which perform particular tasks or implement particular abstract data types. The data, amongst other things, serves as a repository for storing data processed, received, and generated by one or more of the modules.

A person skilled in the art will readily recognize that steps of the methods, presented above, can be performed by programmed computers. Herein, some embodiments are also intended to cover program storage devices, for example, digital data storage media, which are machine or computer readable and encode machine-executable or computer-executable programs of instructions, where said instructions perform some or all of the steps of the described method. The program storage devices may be, for example, digital memories, magnetic storage media, such as a magnetic disks ad magnetic tapes, hard drives, or optically readable digital data storage media.

1. A method for optimizing an anti-sway algorithm for the transport of a load by a hoisting appliance spanning a hoisting area and comprising a trolley, a reeving system and a tool handling the load, the method comprising in a control device:
recording a time-domain signal representative of a measured angle of the load with respect to a vertical Z-axis during operation of the hoisting appliance,
performing a frequency domain analysis on said recorded time-domain signal to estimate frequency components of said time-domain signal,
identifying a primary sway frequency and a secondary sway frequency of the hoisting appliance among said estimated frequency components,
filtering said time-domain signal representative of a measured angle of the load with respect to a vertical Z-axis by a lowpass filter designed to reject said identified secondary sway frequency,
transporting the load in the hoisting area by applying said anti-sway algorithm to said filtered signal.

2. The method for optimizing an anti-sway algorithm according to claim 1, wherein said recording is performed for a set of different lengths between the trolley and the tool and for a set of different masses of the load.

3. The method for optimizing an anti-sway algorithm according to claim 2, wherein said set of different lengths between the trolley and the tool comprises five different lengths spanned between a minimum operating length and a maximum operating length between the trolley and the tool.

4. The method for optimizing an anti-sway algorithm according to claim 2, wherein said set of different masses of the load comprises five different masses spanned between zero and a maximum mass of the load that can be transported by said hoisting appliance.

5. The method for optimizing an anti-sway algorithm according to claim 1, wherein said frequency domain analysis is performed using a transform belonging to the group comprising:
a Discrete Fourier Transform;
a Fast Fourier Transform.

6. The method for optimizing an anti-sway algorithm according to claim 1, wherein said measured angle of the load is recorded using an optical sensor set on said trolley in cooperation with a beacon set on said tool.

7. The method for optimizing an anti-sway algorithm according to claim 5, wherein said primary and secondary sway frequencies are identified for each operating point of said hoisting appliance, an operating point being associated with a couple comprising a value of the mass of the load and a value of the length between the load and the trolley.

8. The method for optimizing an anti-sway algorithm according to claim 1, further comprising filtering said signal representative of said measured angle of the load by a high-pass filter designed to detect said secondary sway frequency, and, when a secondary sway is detected, stopping said hoisting appliance until said detected secondary sway is below a determined amplitude threshold.

9. An apparatus for optimizing an anti-sway algorithm for the transport of a load by a hoisting appliance spanning a hoisting area and comprising a trolley, a reeving system and a tool handling the load, the apparatus comprising:
one or more network interfaces to communicate with a telecommunication network;
a processor coupled to the network interfaces and configured to execute one or more processes; and
a memory configured to store a process executable by the processor, the process when executed operable to:
record a time-domain signal representative of a measured angle of the load with respect to a vertical Z-axis during operation of the hoisting appliance,
perform a frequency domain analysis on said recorded time-domain signal to estimate frequency components of said time-domain signal,
identify a primary sway frequency and a secondary sway frequency of the hoisting appliance among said estimated frequency components,
filter said time-domain signal representative of a measured angle of the load with respect to a vertical Z-axis by a lowpass filter designed to reject said identified secondary sway frequency,
transport the load in the hoisting area by applying said anti-sway algorithm to said filtered signal.

10. The apparatus of claim 11, wherein said process when executed is further operable to perform said recording for a set of different lengths between the trolley and the tool and for a set of different masses of the load.

11. A non-transitory computer-readable recording medium having embodied thereon a computer program for executing the method for optimizing an anti-sway algorithm for the transport of a load by a hoisting appliance spanning a hoisting area and comprising a trolley, a reeving system and a tool handling the load according to claim 1.

12. (canceled)
